(19) United States
(12) Patent Application Publication
(10) Pub. No.: US 2008/0135083 A1
(43) Pub. Date: Jun. 12, 2008

(54) Cascade solar cell with amorphous silicon-based solar cell

(75) Inventors: Li-Hung Lai, Taichung City (TW); Kun-Fang Huang, Taichung (TW); Wen-Sheng Hsieh, Taichung (TW); Li-Wen Lai, Hsinchu Hsien (TW)

Correspondence Address: BACON & THOMAS, PLLC, 625 SLATERS LANE, FOURTH FLOOR, ALEXANDRIA, VA, 22314, US

(73) Assignees: HIGHER WAY ELECTRONIC CO., LTD., Taichung City (TW); Millennium Communication Co., Ltd, Hsinchu Hsien (TW)

(21) Appl. No.: 11/635,624

(22) Filed: Dec. 8, 2006

(51) Int. Cl. H01L 31/00; H01L 31/0256

(52) U.S. Cl. 136/244

(57) ABSTRACT

A cascade solar cell structure includes an amorphous silicon-based solar cell on a non-silicon solar cell to be configured for an anti-reflective surface and absorbing incident light with short wavelength.

### BACKGROUND OF THE INVENTION

1. Field of the Invention

The present invention relates to a cascade solar cell, and more especially, to a cascade solar cell with an amorphous silicon-based top solar cell.

2. Background of the Related Art

Current output of a photovoltaic device is maximized by increasing the total number of photons of differing energy and wavelength which are absorbed by the semiconductor material. The solar spectrum roughly spans the region of wavelength from about 300 nanometers to about 2200 nanometers, which corresponds to from about 4.2 eV to about 0.59 eV, respectively. The portion of the solar spectrum which is absorbed by the photovoltaic device is determined by the value of the optical bandgap energy of the semiconductor material. Solar radiation (sunlight) having an energy less than the optical bandgap energy is not absorbed by the semiconductor material and, therefore, does not contribute to the generation of electricity, current, voltage and power, of the photovoltaic device.

Over the years numerous solar cells have been developed which have met with varying degrees of success. Single junction solar cells are useful but often cannot achieve the power and conversion efficiency of multi-junction solar cells. Unfortunately, multi-junction solar cells and single junction solar cells have been constructed of various materials which are able to capture and convert only part of the solar spectrum into electricity. Multi-junction solar cells have been produced with amorphous silicon and its alloys, such as hydrogenated amorphous silicon carbon and hydrogenated amorphous silicon germanium, with wide and low optical bandgap intrinsic i-layers. Amorphous silicon solar cells have a relatively high open circuit voltage and low current and respond to capture and convert into electricity wavelengths of sunlight from 400 to 900 nanometers (nm) of the solar spectrum.

However, amorphous hydrogenated silicon (a-Si:H) based solar cell technology is currently the leading candidate for large area, low-cost photovoltaic applications. How to utilize amorphous silicon on a photovoltaic device is still one of issues and solution in development high efficiency device.

### SUMMARY OF THE INVENTION

It is an object of the present invention to provide a cascade solar cell having an amorphous-silicon solar cell on a non-silicon based solar cell. The layer/layers of amorphous silicon may absorb incident light with the wavelength from 200 to 600 nm.

It is one of objects of the present invention to provide a cascade solar cell to have a layered structure of amorphous silicon-based on the incident surface of a non-silicon based solar cell. The layered amorphous silicon solar cell may be configured for anti-reflective layer due to its poor dependence on incident angle variation.

Accordingly, one embodiment of the present invention is provided with a cascade solar cell structure having a non-silicon based bottom cell and a layered amorphous silicon-based top cell on the non-silicon based bottom cell.

### BRIEF DESCRIPTION OF THE DRAWINGS

FIG. 1 is a schematic cross-sectional diagram illustrating a cascade solar cell structure in accordance with one embodiment of the present invention.

FIG. 2 is a schematic absorption diagram illustrating the absorption condition of amorphous silicon in accordance with one embodiment of the present invention.

### DETAILED DESCRIPTION OF THE INVENTION

It is advantageous to define several terms before describing the invention. It should be appreciated that the following definitions are used throughout this application.

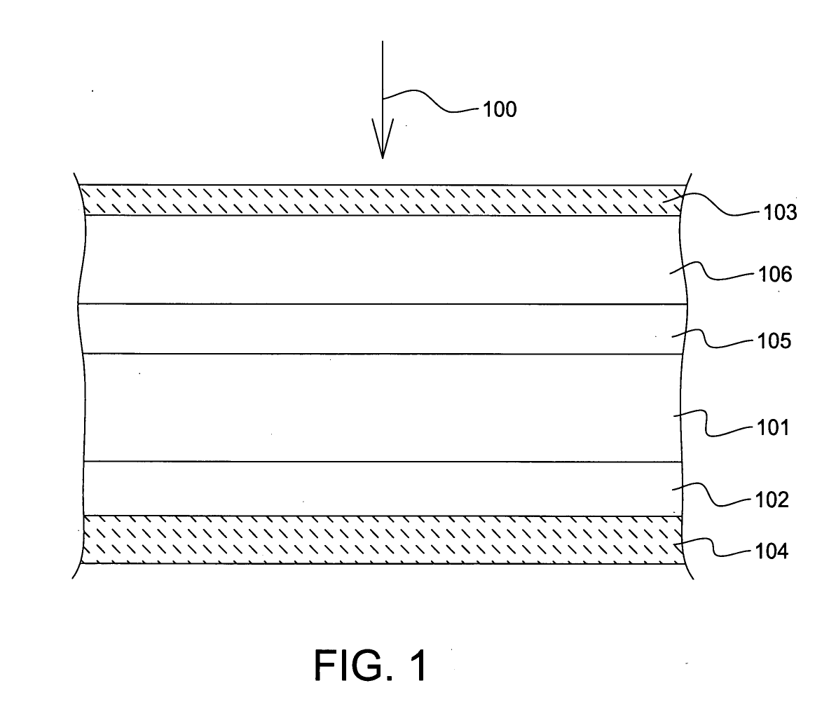

According to the spirit of the present invention, refer to FIG. 1, a cascade solar cell structure has a layered top solar cell on a bottom solar cell. In one embodiment, the bottom solar cell may be various types. For example, a single p-n junction type includes one layer of active material 101 having a single optical bandgap on a bottom-cell substrate 102. Alternatively, a p-n or p-i-n junction type includes some layers of active material 101 having multi optical bandgaps on the bottom-cell substrate 102. It is understood that there are other layers between the layer/layers of active material 101 and the bottom-cell substrate 102, not limited to, such as a buffer layer.

The bottom-cell substrate 102, in one embodiment, may be a GaAs substrate. It is understood that the term “GaAs” refers to a semiconductor composition which may be used as a substrate. Nominally, the prototypical III-V binary semiconductor material consisting of equal parts of the two elements Ga and As are used to form the semiconductor material. It should be appreciated that some deviations, to meet device needs or unwanted impurities, such as Al, may be permitted which continue to use established GaAs fabrication procedures. To permit for anticipated need for impurities or other relatively insignificant modifications, it is prescribed that both Ga and As are present and combine to form an amount of at least 95% of the substrate's entire composition. Additionally, it should be appreciated that the term “substrate” may include any material underneath the active layer. For example, mirror layers, waveguide layers cladding layers or any other layer which is more than twice as thick as the active layer.

Next, in one embodiment, the layer of active material 101 is used as a light-absorbing material. For physical configurations, the layer of active material 101 may be configured as bulk material or thin-films on the bottom-cell substrate 102. The layer of active material 101 may be made of one or multi elements or compounds etc.. For example, the layer of active material 101 may be made of a compound material. The compound material may be III-V or II-VI binary semiconductor material, such as AlAs, AlGaAs, GaAs, InP, InGaAs, CU₂S/(Zn,Cd)S, CuInSe₂/(Zn,Cd)S, and CdTe/n-CdS, etc. Optionally, the layer of active material 101 may be made of single-based material, such as germanium (Ge).

Alternatively, the layer of active material 101 may be made of CIGS (Copper Indium Gallium Selenide) in multi-layered thin-film composites. The term “CIGS” refers to a thin-film composition which may includes chalcopyrite semiconductors, such as thin films of copper-indium-diselenide (CuInSe₂), copper-gallium-diselenide (CuGaSe₂), and Cu(InₓGa₁₋ₓ)Se₂. In another embodiment, the layer of active material 101 may be made of light-absorbing dyes, such as dye-sensitized Ruthenium organometallic dye in a mesoporous layer of nanoparticulate titanium dioxide, etc. Alternatively, the layer of active material 101 may be made of organic/polymer material. For example, the organic semiconductors such as polymers and small-molecule compounds like polyphenylene vinylene, copper phthalocyanine and carbon fullerenes. Accoringly, the bottom solar cell may be any suitable non-silicon based solar cell in the embodiments of the present invention, such as Ge-based solar cell, III-V binary semiconductor solar cell, II-VI binary semiconductor solar cell, dye solar cell (DSC), organic solar cell or CIGS solar cell.

For the layered top solar cell, according to the spirit of the present invention, one or more layers of amorphous silicon 106, doped or not doped or combination, are on the top solar cell. A conductive interface structure 105 may be introduced between the layer/layers of amorphous silicon 106. In the embodiment, the layer/layers of amorphous silicon 106 may be single p-n junction type or p-i-n junction type. Thus, the layer/layers of amorphous silicon 106 may include n-type doped portion, p-type doped portion and no doped portion between thereof. It is understood that the term “amorphous silicon” presents amorphous silicon and amorphous silicon-based material, for example, the amorphous silicon 106 may be a-Si:H, a-SiC:H, a-SiGe:H or a-SiGeC:H, but not limited to.

A conductive interface structure 105, may be between the layer/layers of amorphous silicon 106 and the layer/layers of active material 101. In one embodiment, the conductive interface structure 105 may be a semiconductor tunnel junction, such as GaAs tunnel junction. Alternatively, the conductive interface structure 105, such as a transparent conductive oxide, may include ITO or ZnO, etc. Alternatively, the conductive interface structure 105 may be a film of very thin metal material, such as Au. Furthermore, the two outsides of the layered top solar cell and the bottom solar cell are conductive layers 103 and 104 for contact, such as conductive transparent layer (ITO, ZnO) or metal layer.

Accordingly, when sunlight 100 is incident onto the cascade solar cell structure, sunlight 100 with short wavelength, such as UV wavelength region about 200 to 600 nm, is absorbed by the layered top solar cell first. And then sunlight 100 with visible wavelength is absorbed by the non-silicon based solar cell. In addition to absorption of sunlight with short wavelength, the layered top cell based on amorphous silicon may be configured as an anti-reflective layer for the bottom solar cell.

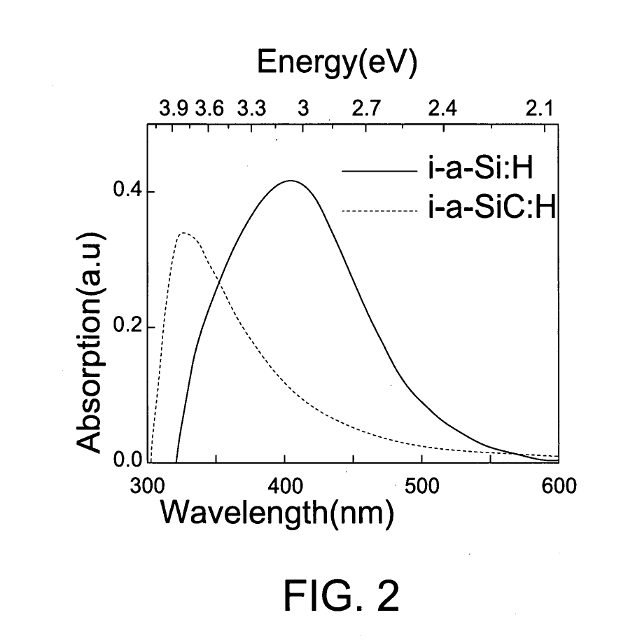

In one embodiment, a method of plasma enhanced chemical vapor deposition (PECVD) may be applied to the formation of amorphous silicon 106 with or without dopant. It is advantageous that the layer of amorphous silicon 106 may absorb incident light in the short wavelength preferably about 350 nm to 450 nm, show in FIG. 2. Furthermore, the light absorption of amorphous silicon 106 is poorly dependent on the factor of incident angle and anti-reflective. Thus, the layer of amorphous silicon 106 may be set in front of the bottom solar cell to absorb incident light in short wavelength that is poorly absorbed by the bottom solar cell. In the embodiment, the layer/layers of amorphous silicon 106 on the bottom solar cell is preferable from 2.7 eV to 4 eV.

Although the present invention has been explained in relation to its preferred embodiment, it is to be understood that other modifications and variation can be made without departing the spirit and scope of the invention as hereafter claimed.

What is claimed is:

1. A cascade solar cell structure, comprising a bottom solar cell and a top solar cell on said bottom solar cell, wherein said top solar cell is an amorphous silicon-based solar cell and sunlight is incident onto said amorphous silicon-based solar cell.

2. The cascade solar cell structure according to claim 1, further comprising conductive interface structure positioned between said bottom solar cell and said top solar cell.

3. The cascade solar cell structure according to claim 2, wherein said conductive interface structure is made of transparent conductive oxide.

4. The cascade solar cell structure according to claim 2, wherein said conductive interface structure is a structure of tunnel junction.

5. The cascade solar cell structure according to claim 2, wherein said conductive interface structure is a film of metal material.

6. The cascade solar cell structure according to claim 1, wherein said amorphous silicon-based solar cell is p-n type junction.

7. The cascade solar cell structure according to claim 1, wherein said amorphous silicon-based solar cell is p-i-n type junction.

8. The cascade solar cell structure according to claim 1, wherein said amorphous silicon-based solar cell comprises n-type and p-type doped amorphous silicon layers.

9. The cascade solar cell structure according to claim 1, wherein said amorphous silicon-based solar cell comprises a non-doped amorphous silicon layer.

10. The cascade solar cell structure according to claim 1, wherein said amorphous silicon-based solar cell is made of a-Si:H, a-SiC:H, a-SiGe:H, or a-SiGeC:H material.

11. The cascade solar cell structure according to claim 1, wherein said bottom solar cell includes a light-absorbing material made of a germanium-based material.

12. The cascade solar cell structure according to claim 1, wherein said bottom solar cell includes a light-absorbing material made of a III-V binary semiconductor material.

13. The cascade solar cell structure according to claim 1, wherein said bottom solar cell includes a light-absorbing material made of a II-VI binary semiconductor material.

14. The cascade solar cell structure according to claim 1, wherein said bottom solar cell includes a light-absorbing material made of an organic compound material.

15. The cascade solar cell structure according to claim 1, wherein said bottom solar cell includes a light-absorbing material made of a ruthenium organometallic dye.

16. The cascade solar cell structure according to claim 1, wherein said bottom solar cell includes a light-absorbing material made of copper indium gallium selenide material.

17. A cascade solar cell structure, comprising a non-silicon based solar cell and an amorphous silicon-based solar cell on said non-silicon based solar cell, wherein said amorphous silicon-based solar cell absorbs sunlight with a wavelength from 200 to 600 nm.

18. The cascade solar cell structure according to claim 17, further comprising a transparent conductive oxide positioned between said non-silicon based solar cell and said amorphous silicon-based solar cell.

19. The cascade solar cell structure according to claim 17, further comprising a structure of tunnel junction positioned between said non-silicon based solar cell and said amorphous silicon-based solar cell.

20. The cascade solar cell structure according to claim 17, further comprising a film of metal material positioned between said non-silicon based solar cell and said amorphous silicon-based solar cell.

21. The cascade solar cell structure according to claim 17, wherein said non-silicon based solar cell comprises a germanium-based solar cell.

22. The cascade solar cell structure according to claim 17, wherein said non-silicon based solar cell comprises a III-V or II-VI binary semiconductor solar cell.

23. The cascade solar cell structure according to claim 17, wherein said non-silicon based solar cell comprises an organic solar cell.

24. The cascade solar cell structure according to claim 17, wherein said non-silicon based solar cell comprises a dye solar cell.

25. The cascade solar cell structure according to claim 17, wherein said non-silicon based solar cell comprises a copper indium gallium selenide solar cell.
